(19) United States
(12) Patent Application Publication
(10) Pub. No.: US 2022/0005680 A1
(43) Pub. Date: Jan. 6, 2022

(54) SPUTTERING DEVICE AND SPUTTERING METHOD

(71) Applicant: Panasonic Intellectual Property Management Co., Ltd., Osaka (JP)

(72) Inventors: DAISUKE SUETSUGU, Osaka (JP); NORIMICHI NOGUCHI, Osaka (JP)

(21) Appl. No.: 17/354,920

(22) Filed: Jun. 22, 2021

(30) Foreign Application Priority Data
Jul. 3, 2020 (JP) 2020-115908

(51) Int. Cl. H01J 37/34; C23C 14/54; C23C 14/35

(52) U.S. Cl. CPC H01J 37/3476; H01J 37/3467; H01J 2237/332; C23C 14/35; C23C 14/54

(57) ABSTRACT

A sputtering device includes: a vacuum chamber in which a target material and a substrate are disposable in a manner of facing each other; a DC power supply being electrically connectable to the target material; a gas supply source configured to introduce a film forming gas containing a nitrogen gas into the vacuum chamber; and a pulsing unit configured to pulse a current flowing from the DC power supply to the target material. The sputtering device forms a nitride thin film having a ternary or more composition containing nitrogen on the substrate by generating plasma in the vacuum chamber using a sintered alloy target material having a binary or more composition as the target material.

### BACKGROUND

### 1. Technical Field

The present invention relates to a sputtering device and a sputtering method for forming a nitride resistor thin film on a substrate such as a semiconductor wafer.

### 2. Description of the Related Art

In recent years, a device such as a resistor or a thermistor in which a thin film is formed on a substrate and is formed into a desired pattern is required to have a higher resistance range, and a necessity for a technique of forming a nitride thin film having a higher specific resistance than an alloy-based material such as nichrome is increased.

In general, from a viewpoint of a production rate and production stability, the nitride thin film is formed by reactive sputtering in which a target material serving as a raw material and a reaction gas are reacted and deposited.

In a related art, there is a sputtering method in which a nitridation degree is controlled using a flow rate of nitrogen which is a reaction gas and a film-forming pressure (see, for example, Japanese Patent No. 2579470)

Therefore, a reactive sputtering method in the related art will be described mainly with reference to FIG. 12. Here, FIG. 12 is a schematic cross-sectional view showing a reactive sputtering device in the related art.

Vacuum chamber 1 can be depressurized by evacuating vacuum pump 2 connected via valve 3 to be in a vacuum state. Gas supply source 4 can supply a gas containing nitrogen to vacuum chamber 1 at a constant rate. A vacuum degree in vacuum chamber 1 can be controlled to a desired gas pressure by changing an opening and closing ratio of valve 3. Target material 7 is disposed in vacuum chamber 1. Backing plate 8 supports target material 7. DC power supply 30 is electrically connected to backing plate 8, and a voltage is applied to target material 7 via backing plate 8, so that a part of the gas in vacuum chamber 1 is dissociated to generate plasma. In vacuum chamber 1, substrate 6 faces target material 7. Substrate holder 5 is disposed below substrate 6 and supports substrate 6.

By the plasma generated in vacuum chamber 1, target material 7 is sputtered and ejected and reaches substrate 6, and thin films of target material 7 are deposited. At the same time, the gas and the plasma in the vacuum chamber react with target material 7 which is being deposited on the substrate, thereby obtaining a nitride thin film.

A ratio of nitrogen contained in the nitride thin film has a correlation with electrical properties such as a specific resistance and a temperature coefficient (TCR) thereof which are important in a resistance device, and the gas supplied from gas supply source 4 is adjusted using a mixing ratio of nitrogen which reacts with the thin film and an inert gas such as argon which does not react with the thin film so that the electrical properties are desired values.

### SUMMARY

A sputtering device according to an aspect of the present invention includes: a vacuum chamber in which a target material and a substrate are disposable in a manner of facing each other; a DC power supply being electrically connectable to the target material; a gas supply source configured to introduce a film forming gas containing a nitrogen gas into the vacuum chamber; and a pulsing unit configured to pulse a current flowing from the DC power supply to the target material. The sputtering device forms a nitride thin film having a ternary or more composition containing nitrogen on the substrate by generating plasma in the vacuum chamber using a sintered alloy target material having a binary or more composition as the target material.

A sputtering method according to an aspect of the present invention includes: a step of preparing a vacuum chamber in which a target material and a substrate are disposable in a manner of facing each other; a step of electrically connecting a DC power supply to the target material; a step of introducing a film forming gas containing a nitrogen gas into the vacuum chamber; a step of detecting an emission spectrum of the plasma generated in the vacuum chamber; a step of calculating an emission intensity ratio of a film forming gas containing the target material and a nitrogen gas based on a position and an intensity of a characteristic peak of the detected emission spectrum; and a step of setting an ON/OFF time of a pulse based on the calculated emission intensity ratio of the film forming gas, and pulsing a current flowing through the target material.

### BRIEF DESCRIPTION OF DRAWINGS

FIG. 1 is a schematic cross-sectional view showing a configuration of a sputtering device according to a first embodiment.

FIG. 2 is a graph showing a relationship between an N₂ gas flow rate ratio and a specific resistance according to a first comparative example.

FIG. 3 is a graph showing a relationship between the N₂ gas flow rate ratio and a TCR according to the first comparative example.

FIG. 4 is a graph showing a relationship between a pulse on-time and a specific resistance in a sputtering method according to a first example.

FIG. 5 is a graph showing a relationship between the pulse on-time and a TCR in the sputtering method according to the first example.

FIG. 6 is a graph showing a relationship between the pulse on-time and a Si composition ratio in a CrSi alloy in the sputtering method according to the first example.

FIG. 7 is a schematic cross-sectional view showing a configuration of a sputtering device according to a second embodiment.

FIG. 8A is a diagram showing a measurement example of a plasma emission spectrum in a sputtering method according to the second embodiment.

FIG. 8B is a partially enlarged view showing an emission peak of Si and a peripheral emission spectrum.

FIG. 8C is a partially enlarged view showing an emission peak of Cr and a peripheral emission spectrum.

FIG. 8D is a partially enlarged view showing an emission peak of N₂ and a peripheral emission spectrum.

FIG. 8E is a partially enlarged view showing an emission peak of Ar and a peripheral emission spectrum.

FIG. 9 is a graph showing a specific resistance and a TCR of a nitride thin film formed in the second embodiment.

FIG. 10A is a graph showing a relationship between an N₂ gas flow rate and a TCR in a sputtering method according to a third example, and shows a case in which a pulse on-time is controlled from the minimum to the maximum.

FIG. 10B is a graph showing a relationship between the N₂ gas flow rate and a specific resistance in the sputtering method according to the third example, and shows a case in which the pulse on-time is controlled from the minimum to the maximum.

FIG. 11A is a graph showing a relationship between a pulse on-time and an N₂ emission intensity ratio in a sputtering method according to a fourth example, and shows a case in which an N₂ gas flow rate is changed.

FIG. 11B is a graph showing a relationship between the pulse on-time and an Si emission intensity ratio in the sputtering method according to the fourth example, and shows a case in which the N₂ gas flow rate is changed.

FIG. 12 is a schematic cross-sectional view showing a configuration of a sputtering device in a related art.

### DETAILED DESCRIPTIONS

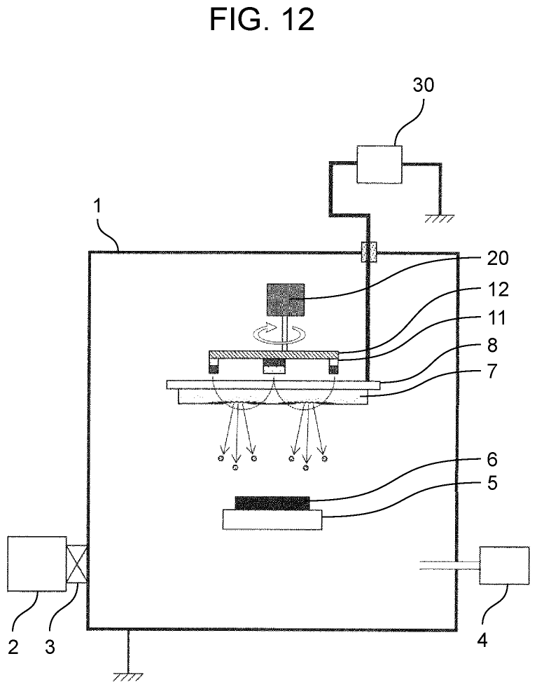

For a reactive sputtering device in a related art (see FIG. 12), it is difficult to precisely control a nitridation degree of a thin film due to a limit of a resolution of a mass flow controller that sets a gas flow rate, it is difficult to accurately adjust a specific resistance and a temperature coefficient TCR of the thin film to desired values, and it is difficult to stably perform production.

In a case of a ternary or more nitride thin film capable of attaining a higher specific resistance, for example, in a case of a ternary nitride thin film, when a metal A-metal Bx-nitrogen Ny is formed, a metal AB alloy is used as target material 7. However, the specific resistance and the TCR are different depending on an AB ratio. That is, although it is necessary to precisely control not only a nitridation degree y but also an AB ratio x, when the AB ratio x of target material 7 which is a raw material varies at a time of manufacturing a target, electrical characteristics also change. Further, when target material 7 is consumed, the AB ratio x may change and the electrical characteristics may also change, which makes it more difficult to stably perform production.

In view of the above-described problems in the related art, an object of the present invention is to provide a sputtering device and a sputtering method that are capable of controlling a composition ratio of a nitride thin film with high accuracy and stably forming the film.

A sputtering device according to a first aspect includes: a vacuum chamber in which a target material and a substrate are capable of being disposed in a manner of facing each other; a DC power supply capable of being electrically connected to the target material; a gas supply source configured to introduce a film forming gas containing a nitrogen gas into the vacuum chamber; and a pulsing unit configured to pulse a current flowing from the DC power supply to the target material, in which a nitride thin film having a ternary or more composition containing nitrogen is formed on the substrate by generating plasma in the vacuum chamber using a sintered alloy target material having a binary or more composition as the target material.

A sputtering device according to a second aspect includes: a viewport configured to observe the plasma generated in the vacuum chamber; a spectroscope configured to detect an emission spectrum of the plasma; an emission spectrum calculator configured to calculate at least one of an emission intensity ratio of the target material and an emission intensity ratio of nitrogen based on a position and an intensity of a characteristic peak of the detected emission spectrum; and a pulse controller configured to set an ON/OFF time of a pulse in the pulsing unit based on the calculated at least one emission intensity ratio.

A sputtering method according to a third aspect using the sputtering device according to the first aspect or the second aspect described above includes: setting an ON/OFF time of a pulse in the pulsing unit, and changing a composition ratio of a binary or more metal contained in the nitride thin film.

According to the above-described configuration, even when a composition is different depending on the lot of a target material or even when the target material is consumed due to film formation for a long time, a gas flow rate and a pulse condition can be changed according to a state of the target material from an emission spectrum of a plasma. Therefore, since a variation in electrical characteristics is minimized, for example, a nitride resistance thin film can be stably formed.

A sputtering method according to a fourth aspect using the sputtering device according to the second aspect includes: a step of measuring the plasma generated in the vacuum chamber by the spectroscope; a step of normalizing an emission intensity of a current value of the measured emission peak of the plasma with a value of an emission intensity in a plasma state serving as a reference value recorded in advance to obtain a normalized emission intensity; a step of calculating an emission intensity ratio of nitrogen in the entire film forming gas; and a step of feedback-controlling a pulse on-time such that the emission intensity ratio of nitrogen minimizes a difference between the reference value and the current value.

A sputtering method according to a fifth aspect includes: a step of preparing a vacuum chamber in which a target material and a substrate are capable of being disposed in a manner of facing each other; a step of electrically connecting a DC power supply to the target material; a step of introducing a film forming gas containing a nitrogen gas into the vacuum chamber; a step of detecting an emission spectrum of the plasma generated in the vacuum chamber; a step of calculating an emission intensity ratio of a film forming gas containing the target material and a nitrogen gas based on a position and an intensity of a characteristic peak of the detected emission spectrum; and a step of setting an ON/OFF time of a pulse based on the calculated emission intensity ratio of the film forming gas and pulsing a current flowing through the target material.

A sputtering method according to a sixth aspect includes: a step of calculating, in the step of calculating the emission intensity ratio of the film forming gas in the fifth aspect, a normalized emission intensity of nitrogen obtained by normalizing a current value of an emission intensity at the characteristic peak of nitrogen in the detected emission spectrum with a value of an emission intensity of nitrogen in a plasma state serving as a reference value recorded in advance; and a step of feedback-controlling a pulse on-time such that the emission intensity ratio of nitrogen in the entire film forming gas minimizes a difference between the reference value and the current value.

According to the sputtering device and the sputtering method in the present invention, a composition of the ternary or more nitride thin film can be precisely controlled according to pulse discharge conditions. Therefore, the specific resistance and the TCR can be finely adjusted to desired values.

Hereinafter, a sputtering device and a sputtering method according to embodiments will be described in detail with reference to the drawings. In the drawings, substantially the same components are denoted by the same reference numerals.

### First Embodiment

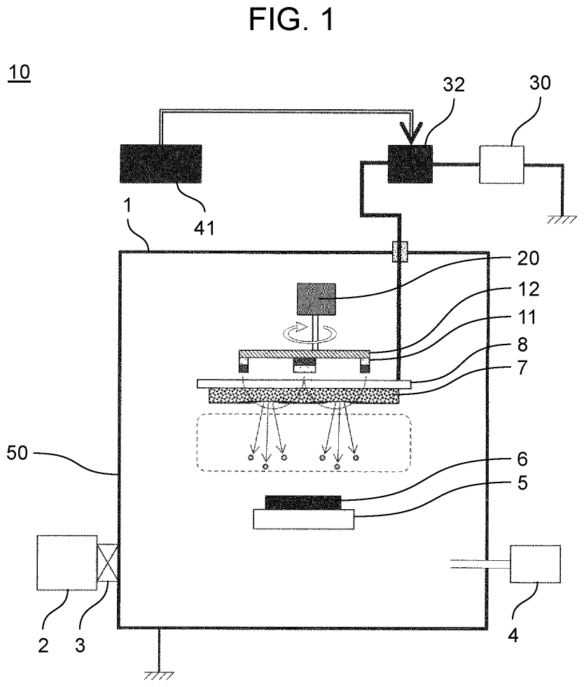

First, a configuration of sputtering device 10 according to the first embodiment will be described mainly with reference to FIG. 1. FIG. 1 is a schematic cross-sectional view showing the configuration of sputtering device 10 according to the first embodiment.

Sputtering device 10 includes vacuum chamber 1, DC power supply 30, pulsing unit 32, and pulse controller 41. In vacuum chamber 1, target material 7 and substrate 6 can be disposed in a manner of facing each other. DC power supply 30 can be electrically connected to target material 7. Pulsing unit 32 pulses a current flowing from DC power supply 30 to target material 7. Pulse controller 41 sets a pulse on-time and a pulse off-time in pulsing unit 32.

According to sputtering device 10 in the first embodiment, a composition of a ternary or more nitride thin film can be precisely controlled according to pulse discharge conditions set by pulse controller 41. Therefore, a specific resistance and a TCR can be finely adjusted to desired values.

Hereinafter, each component of sputtering device 10 will be described.

Vacuum Chamber

Vacuum chamber 1 can be depressurized to be in a vacuum state by evacuating vacuum pump 2 connected via valve 3.

Gas Supply Source

Gas supply source 4 includes a gas source such as a gas cylinder and a flow rate controller such as a mass flow controller, and can supply gas necessary for sputtering to vacuum chamber 1 at a constant rate. As the gas supplied from gas supply source 4, for example, gas such as nitrogen or oxygen having reactivity with a target material or mixed gas of gas having reactivity and rare gas such as argon can be selected.

Valve

A vacuum degree in vacuum chamber 1 can be controlled to a desired gas pressure by changing an opening and closing ratio of valve 3.

Target Material

In FIG. 1, target material 7 is disposed in an upper part in vacuum chamber 1. Target material 7 is a metal material having a binary or more composition, and for example, a combination of silicon and a transition metal can be selected as a material having a high specific resistance. For example, silicon can be selected as a metal A of the binary alloy AB, and tantalum, niobium, chromium, or the like can be selected as a metal B. Oxygen may be contained in a range of being a conductor of target material 7. That is, a trace amount of oxygen that is contained in the target obtained by sintering atomized powder of a metal serving as the raw material is also contained.

Backing Plate

Backing plate 8 supports target material 7.

DC Power Supply

DC power supply 30 is electrically connected to target material 7 via pulsating unit 32 and backing plate 8, and can apply a voltage to target material 7.

Pulsing Unit

Pulsing unit 32 can accumulate a direct current generated by DC power supply 30 in a built-in capacitor or the like, turn the direct current on and off by a built-in semiconductor switching element or the like, and pulse the direct current. In switching between ON and OFF, a configuration that can be set as a digital value can be selected, and a resolution of time setting can be set to, for example, 1 μsec or less.

Pulse Controller

Pulse controller 41 controls an ON time and an OFF time of a pulse to be instructed to pulsing unit 32 based on a relationship of a pulse condition for generating plasma and electrical properties of the thin film.

Magnet and Yoke

Magnet 11 and yoke 12 are disposed on a back surface of backing plate 8, and can generate a magnetic field on a surface of target material 7. The number of magnets 11 may be one or more. Magnet 11 may be either a permanent magnet or an electromagnet. Yoke 12 is connected to one end of magnet 11, constitutes a magnetic circuit, and can prevent leakage of unnecessary magnetic field to a side opposite to target material 7. Magnet 11 and yoke 12 concentrate the plasma at a position where a parallel magnetic field with respect to a plane of target material 7 is maximized, thereby improving a deposition rate. The position where the plasma is concentrated is referred to as an erosion. When erosion concentrates at a specific position, only a part of target material 7 is consumed, and the material cannot be efficiently used. Therefore, magnet 11 and yoke 12 may be moved in parallel to a surface of target material 7 by magnet rotation mechanism 20 to move an erosion position.

Substrate and Substrate Holder

In FIG. 1, substrate 6 facing target material 7 is disposed in a lower part in vacuum chamber 1. Substrate holder 5 is disposed below substrate 6 and supports substrate 6.

Operation of Sputtering Device

Next, an operation of sputtering device 10 according to the first embodiment will be described, and a sputtering method according to the first embodiment will also be described (similar applies to a second embodiment).
(1) First, target material 7 is set in vacuum chamber 1, and substrate 6 is set substantially horizontally below target material 7.
(2) Next, vacuum pump 2 is operated to depressurize the inside of vacuum chamber 1 to a vacuum state. After reaching a predetermined vacuum degree, the gas is introduced from gas supply source 4, and an opening degree of gate valve 3 is adjusted to attain a predetermined gas pressure.
(3) Then, a voltage is generated by DC power supply 30, the voltage is pulsed by pulsing unit 32 switching between the predetermined ON time and OFF time, and the pulsed voltage is applied to target material 7, thereby generating plasma in vacuum chamber 1.
(4) By the pulsed plasma generated in vacuum chamber 1, target material 7 is sputtered and ejected and reaches substrate 6, and thin films containing an element constituting the target material is deposited. At the same time, the gas and the plasma in vacuum chamber 1 react with the target material which is being deposited on substrate 6. During the OFF time of a voltage application, the gas and the plasma in vacuum chamber 1 react with the target material deposited on substrate 6, thereby forming a thin film of a compound obtained by the dense target material and the gas reacting with each other.

By repeating the continuous pulse film formation a predetermined number of times, a nitride thin film is deposited on substrate 6.

### FIRST COMPARATIVE EXAMPLE

In the first comparative example, a nitride thin film was formed in the configuration in the related art shown in FIG. 12, that is, in the configuration in which DC power supply 30 was directly connected to target material 7. At this time, the film formation was performed on a glass substrate under film formation conditions that an ultimate vacuum degree was fixed to 1×10⁻⁴ Pa or less, the film-forming pressure was fixed to 0.45 Pa, an electric power of DC power supply 30 was fixed to 100 W, an Ar gas flow rate was 15 sccm, and a nitrogen gas flow rate was changed in a range of 3.0 sccm to 5.5 sccm. At this time, the film formation was performed under a condition that the gas flow rate was changed in a range from 3.8 sccm to 4.2 sccm every 0.1 sccm, which is the used minimum resolution of the mass flow controller.

### FIRST EXAMPLE

In a first example, a nitride thin film was formed in the configuration according to the first embodiment. At this time, a sample for resistance measurement was formed on the glass substrate under film formation conditions that when the ultimate vacuum degree was 1×10⁻⁴ Pa or less, the film-forming pressure was 0.45 Pa, and the electric power of DC power supply 30 was 100 W, the Ar gas flow rate was fixed to 15 sccm, the nitrogen gas flow rate was fixed to 4.1 sccm, the pulse period (=pulse on-time+pulse off-time) was 100 μsec, and change is performed every 1 μsec, which is the minimum resolution of a pulse controller using the pulse on-time. Under some conditions, a film was formed on a sapphire substrate not containing Si as a sample for a composition analysis.

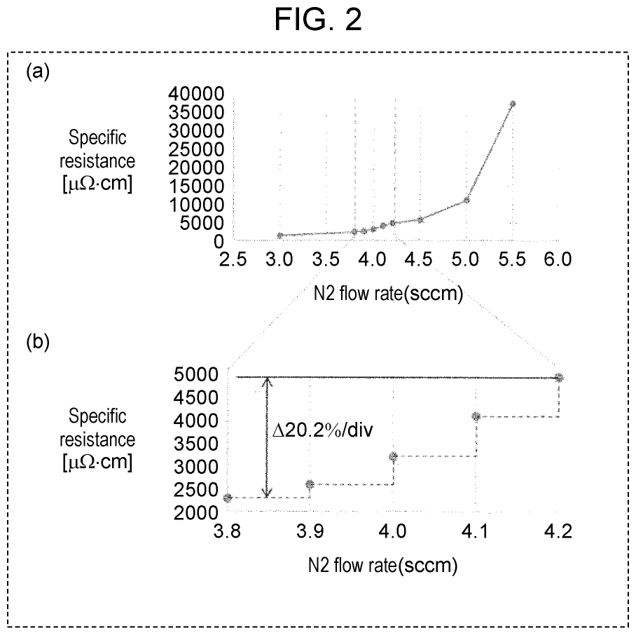

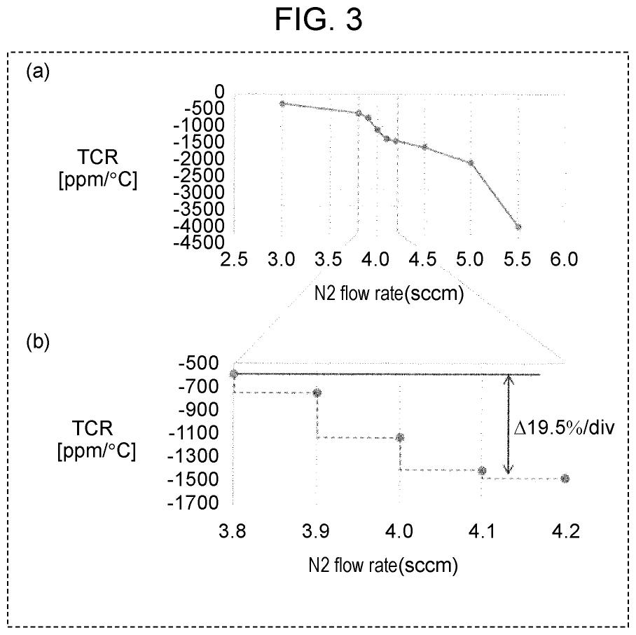

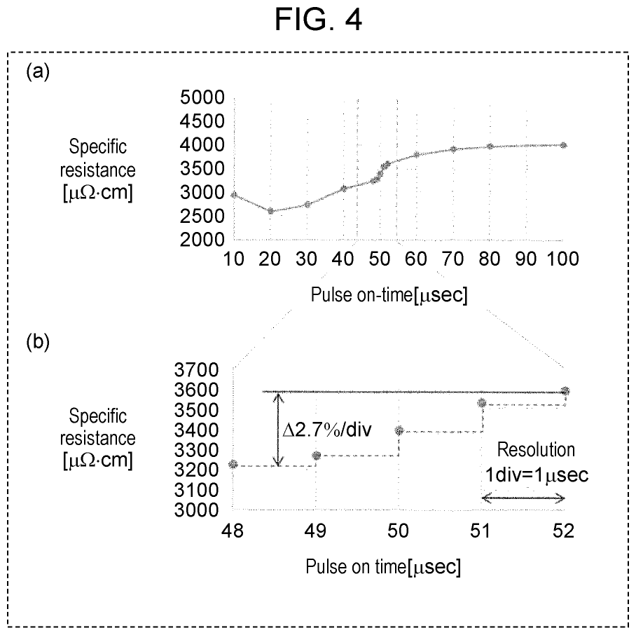

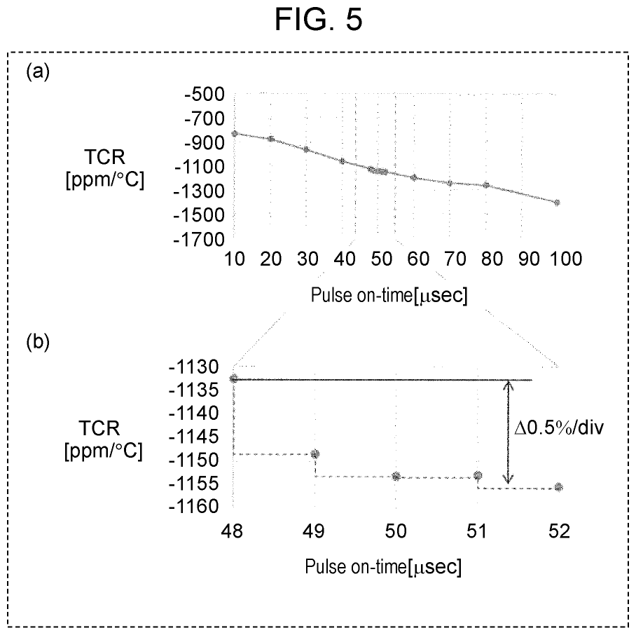

(a) of FIG. 2 is a graph showing a relationship between an N₂ gas flow rate ratio and a specific resistance according to the first comparative example, and (b) of FIG. 2 is a partially enlarged view showing an enlarged part of the graph of (a) of FIG. 2. (a) of FIG. 3 is a graph showing a relationship between the N₂ gas flow rate ratio and a TCR according to the first comparative example, and (b) of FIG. 3 is a partially enlarged view showing an enlarged part of the graph of (a) of FIG. 3. (a) of FIG. 4 is a graph showing a relationship between a pulse on-time and a specific resistance in a sputtering method according to the first example, and (b) of FIG. 4 is a partially enlarged view showing a part of the graph of (a) of FIG. 4. (a) of FIG. 5 is a graph showing a relationship between the pulse on-time and a TCR in the sputtering method according to the first example, and (b) of FIG. 5 is a partially enlarged view showing a part of the graph of (a) of FIG. 5.

A film thickness of the formed thin film sample was measured using a stylus type profilometer, and a sheet resistance value was measured based on a four-probe method and was calculated as sheet resistance [Ω/□]×film thickness [cm]=specific resistance [Ω·cm]. A similar resistance measurement was performed in a state in which the sample was heated on a hot plate, and a slope ΔR÷R0÷ΔT [ppm/° C.] of the resistance value change with respect to the temperature was calculated. The temperature at which the resistance measurement was performed was 40° C., 75° C., and 110° C., and the TCR was calculated by setting the resistance value at 40° C. to R0. For the sample for the composition analysis according to the first example, a composition ratio of Si and Cr was measured based on a fundamental parameter method (FP method) using fluorescent X-rays (XRF).

The graph of (a) of FIG. 2 shows a dependence of the specific resistance of a thin film resistor formed in the first comparative example on the N₂ flow rate of 3.0 sccm to 5.5 sccm, and it was found that the specific resistance tends to increase as the N₂ flow rate increases. The graph of (b) of FIG. 2 is a partially enlarged view showing the range of the N₂ flow rate from 3.8 sccm to 4.2 sccm. (b) of FIG. 2 shows a controllability of the specific resistance when the N₂ gas flow rate is changed every 0.1 sccm, which is the resolution of the mass flow controller that controls the N₂ gas flow rate. In this range, a changing rate of the specific resistance per resolution is 20.2%. The changing rate of the specific resistance per resolution is a normalized value obtained by dividing a difference between a specific resistance at a lower limit value of 3.8 sccm of the N₂ flow rate and a specific resistance at an upper limit value of 4.2 sccm of the N₂ flow rate in a measurement range in the graph of (b) of FIG. 2 by a value of 4 (dimensionless) obtained by dividing a width of 0.4 sccm of the upper limit value and the lower limit value by the resolution of 0.1 sccm of the N₂ flow rate, and by dividing the difference by a specific resistance at a central value of 4.0 sccm of the N₂ flow rate.

The graph of FIGS. 3A and 3B shows a dependence of the TCR of the thin film resistor formed in the first comparative example on the N₂ flow rate of 3.0 sccm to 5.5 sccm, and it was found that a negative absolute value of the TCR tends to increase as the N₂ flow rate increases. The graph of (b) of FIG. 3 is a partially enlarged view showing the range of the N₂ flow rate from 3.8 sccm to 4.2 sccm, and shows a controllability of the TCR when the N₂ gas flow rate is changed every 0.1 sccm, which is the resolution of the mass flow controller that controls the N₂ gas flow rate. In this range, a changing rate of the TCR per resolution is 19.5%. The changing rate of the TCR per resolution is a normalized value obtained by dividing a difference between a TCR at the lower limit value of 3.8 sccm of the N₂ flow rate and a TCR at the upper limit value of 4.2 sccm of the N₂ flow rate in a measurement range in the graph of (b) of FIG. 3 by the value of 4 (dimensionless) obtained by dividing the width of 0.4 sccm of the upper limit value and the lower limit value by the resolution of 0.1 sccm of the N₂ flow rate, and by dividing the difference by a TCR at the central value of 4.0 sccm of the N₂ flow rate.

The graph of (a) of FIG. 4 shows a dependence of the specific resistance of the thin film resistor formed in the first example on the pulse on-time of 10 μsec to 100 μsec when the N₂ flow rate is 4.1 sccm and the pulse period is 100 μsec, and the specific resistance tends to increase as the pulse on-time increases. The graph of (b) of FIG. 4 is a partially enlarged view showing a range of the pulse on-time from 48 μsec to 52 μsec, and shows a controllability of the specific resistance when the specific resistance is changed every 1 μsec, which is a time resolution of pulsing unit 32 that controls the pulse. In this range, a changing rate of the specific resistance per resolution is 2.7%. The changing rate of the specific resistance per resolution is a normalized value obtained by dividing a difference between a specific resistance at a lower limit value of 48 μsec of the pulse on-time and a specific resistance at an upper limit value of 52 μsec of the pulse on-time in a measurement range by the value 4 (dimensionless) obtained by dividing the width of 4 μsec of the upper limit value and the lower limit value by the resolution of 1 μsec of the pulse on-time, and by dividing the difference by a specific resistance at a central value of 50 μsec of the pulse on-time.

The graph of (a) of FIG. 5 shows a dependence of the TCR of the thin film resistor formed in the first example on the pulse on-time of 10 μsec to 100 μsec, and it was found that the negative absolute value of the TCR tends to increase as the pulse on-time increases. The graph of (b) of FIG. 5 is an enlarged view showing the pulse on-time in the range from 48 μsec to 52 μsec, and shows a controllability of the TCR when the TCR is changed every 1 μsec, which is the time resolution of pulsing unit 32 that controls the pulse. In this range, a changing rate of the TCR per resolution is 0.5%. The changing rate of the TCR per resolution is a normalized value obtained by dividing a difference between a TCR at the lower limit value of 48 μsec of the pulse on-time and a TCR at the upper limit value of 52 μsec of the pulse on-time in the measurement range by the value 4 (dimensionless) obtained by dividing the width of 4 μsec of the upper limit value and the lower limit value by the resolution of 1 μsec of the pulse on-time, and by dividing the difference by a TCR at the central value of 50 μsec of the pulse on-time.

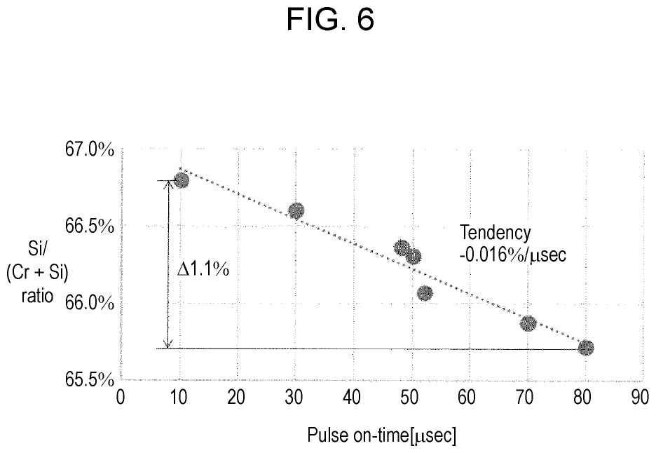

FIG. 6 is a graph showing a relationship between the pulse on-time and a Si composition ratio in a CrSi alloy in the sputtering method according to the first example. As shown in FIG. 6, it was found that Si ratio=Si/(Si+Cr) tends to decrease as the pulse on-time increases. In this range, a changing rate of the Si ratio is −0.016%/μsec. Although an influence is small at approximately 1 μsec which is the resolution of the pulse on-time, when being changed from 10 μsec to 70 μsec, the Si ratio can be finely adjusted with a width of 41.1%.

Accordingly, it was found that in pulse sputtering device 10, the specific resistance and the TCR, which are the electrical characteristics, can be controlled more finely by controlling the pulse on-time rather than controlling the N₂ gas flow rate. That is, the pulse on-time has a high resolution for controlling the specific resistance and the TCR. Therefore, it is possible to form a film by precisely adjusting the pulse on-time and the pulse off-time, and it is possible to form a thermistor or a resistance device with higher accuracy.

When an alloy composition of target material 7 is deviated within a range of less than 1% due to manufacturing variations or the like, it is possible to cope with the deviation by changing a condition of the pulse on-time.

When the TCR is desired to be zero in a resistance device or the like, the TCR can be adjusted by performing a heat treatment at a predetermined temperature for a predetermined time by utilizing a fact that the TCR changes from negative to positive by a heat treatment at a temperature of 300° C. to 600° C. for a processing time of approximately 1 hour to 5 hours after a film formation.

### Second Embodiment

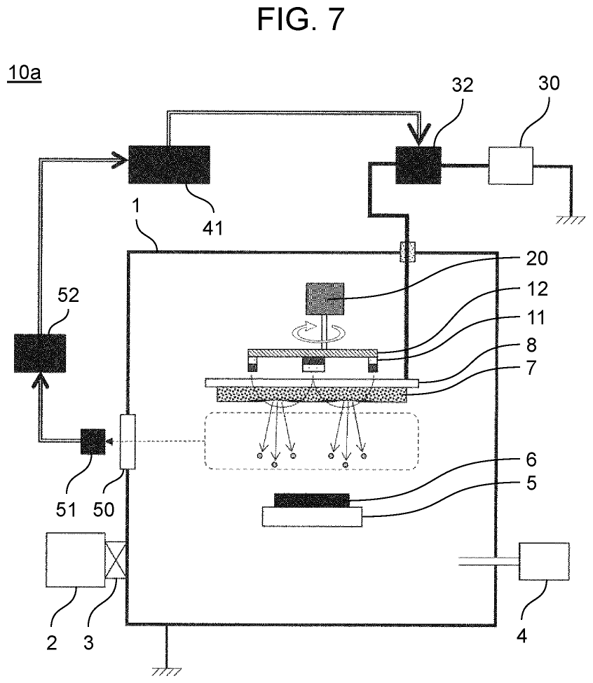

Next, a configuration of sputtering device l0a according to a second embodiment will be described mainly with reference to FIG. 7.

Here, FIG. 7 is a schematic cross-sectional view showing the configuration of sputtering device l0a according to the second embodiment. In FIG. 7, the same or corresponding parts as or to the parts shown in FIG. 1 are denoted by the same reference numerals, and a part of the description thereof will be omitted.

In FIG. 7, viewport 50 that allows plasma emission to be observed from an outside of the vacuum chamber, spectroscope 51 that allows a spectrum of the plasma emission to be observed, and emission spectrum calculator 52 that calculates a component ratio of the plasma based on the emission spectrum are disposed on a side wall of vacuum chamber 1. Sputtering device l0a is different from the sputtering device according to the first embodiment in that emission spectrum calculator 52 is connected to pulse controller 41, and the pulse condition can be feedback-controlled based on the obtained component ratio of the plasma.

Measurement of Spectrum of Plasma Emission

Measurement of the spectrum of the plasma emission will be described. An emission intensity of the pulsed plasma generated in vacuum chamber 1 fluctuates at a period of approximately 50 μsec to 1 msec, which can be set by pulsing unit 32. In a case in which magnet 11 and yoke 12 are moved by magnet rotation mechanism 20 to move the erosion position in order to efficiently use the material, a spatial position of the plasma is moved, and thus an emission intensity of the plasma detected from viewport 50 also fluctuates. A rotation period of magnet 11 is approximately 0.1 sec to 10 sec. Therefore, it is necessary to set an integration time at a time of measurement by spectroscope 51 to be longer than at least a fluctuation period of the pulsed plasma. It is desirable to match the integration time with the rotation period of magnet 11, and the measurement may be performed at a timing at which time fluctuation of the emission intensity due to the rotation of magnet 11 is observed and the maximum value is reached.

Calculation of Emission Intensity Ratio

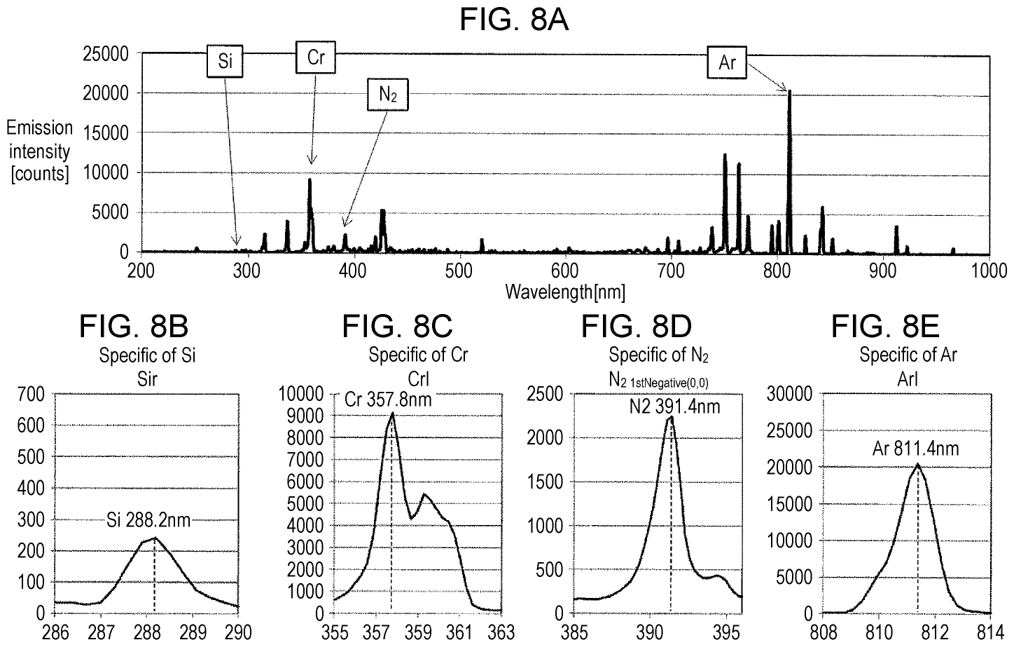

The calculation of the emission intensity ratio of the plasma will be described using an example of the spectrum of the emission. The spectrum of the emission in FIG. 8A is a result of measuring the plasma emission under conditions of an Ar flow rate of 16 sccm, an N₂ flow rate of 4 sccm, a pulse on-time of 100 μsec, and a pulse off-time of 100 μsec using Cr₃₀Si₇₀ alloy as target material 7 at an exposure time of 1 msec by spectroscope 51.

As shown in FIG. 8A, the spectrum of the plasma emission has a large number of emission peaks. The emission peaks are obtained by gas particles such as Ar (FIG. 8E) and N₂ (FIG. 8D) and sputtered particles such as Cr (FIG. 8C) and Si (FIG. 8B) being excited and emitted by collision with charged particles such as electrons constituting the plasma. That is, the emission peak has a plurality of wavelength peaks corresponding to energy levels each specific to a respective atom or molecule. Therefore, the peak is selected under a condition that the peak is a relatively strong emission peak and the emission peaks of the atoms and molecules do not overlap with one another and can be determined. For example, 288.2 nm is selected for Si, 357.8 nm is selected for Cr ions, 391.4 nm is selected for N₂ molecular ions, and 811.4 nm is selected for Ar ions.
(A) First, the number of counts at each peak position is totalized, and the other peaks Si, Cr, and N₂ are divided by the number of counts of Ar to obtain the emission intensities of a current value, which are defined as I₁(Si), I₁(Cr), and I₁(N₂).
(B) Next, Ir₁(N₂)=I₁(N₂)/(I₁(Si)+I₁(Cr)+I₁(N₂)) is set as an emission intensity ratio of N₂. I₁(Si)=I₁(Si)/(I₁(Si)+I₁(Cr)) is set as an emission intensity ratio of Si and Cr.
(C) Next, the emission intensity ratio Ir₁(N₂) of N₂ and the emission intensity ratio Ir₁(Si) of Si and Cr are divided by the emission intensity ratio Ir₀(N₂) of N₂ in a plasma state serving as a reference value recorded in advance and the emission intensity ratio Ir₀(Si) of Si and Cr to obtain a normalized emission intensity ratio I_{N2}=Ir₁(N₂)/Ir₀(N₂) of N₂ and a normalized emission intensity ratio I_{Si}=Ir₁(Si)/Ir₀(Si) of Si and Cr.

### SECOND EXAMPLE

In the second example, a nitride thin film was formed under the following film formation conditions in the configuration of the sputtering device according to the second embodiment. At this time, in the film formation condition, when an ultimate vacuum degree was 1×10⁻⁴ Pa or less, the film-forming pressure was 0.45 Pa, and an electric power of DC power supply 30 was 100 W, an Ar gas flow rate was fixed to 15 sccm, and a nitrogen gas flow rate was fixed to 4.1 sccm. A pulse period (=pulse on-time+pulse off-time) was set to 201 μsec, a plasma discharge was performed at a pulse on-time of 97 μsec at a time of an initial film formation, and the N₂ emission intensity ratio calculated by emission spectrum calculator 52 was recorded as reference data based on the observation data on spectroscope 51 to form a film. In a next film formation, the pulse period (=pulse on-time+pulse off-time) was set to 201 μsec, the pulse on-time was changed every 1 μsec, which is the minimum resolution of the pulse controller, centering on a previous set value of 97 μsec, the pulse on-time was set to a pulse on-time at which a difference from the recorded N₂ emission intensity ratio was minimized, and a film formation experiment was performed three times as a whole.

### SECOND COMPARATIVE EXAMPLE

In the second comparative example, with the configuration of the sputtering device according to the second embodiment, a nitride thin film was formed under different film formation conditions from the second embodiment as follows. At this time, in the film formation condition, when the ultimate vacuum degree was 1×10⁻⁴ Pa or less, the film-forming pressure was 0.45 Pa, and an electric power of DC power supply 30 was 100 W, an Ar gas flow rate was fixed to 15 sccm, and a nitrogen gas flow rate was fixed to 4.1 sccm. The pulse period (=pulse on-time 30 pulse off-time) was set to 201 μsec, and was fixed under a condition that the pulse on-time was fixed to 100 μsec, that is, the plasman emission intensity ratio was not fed back to the pulse condition, and the film formation experiment was performed twice.

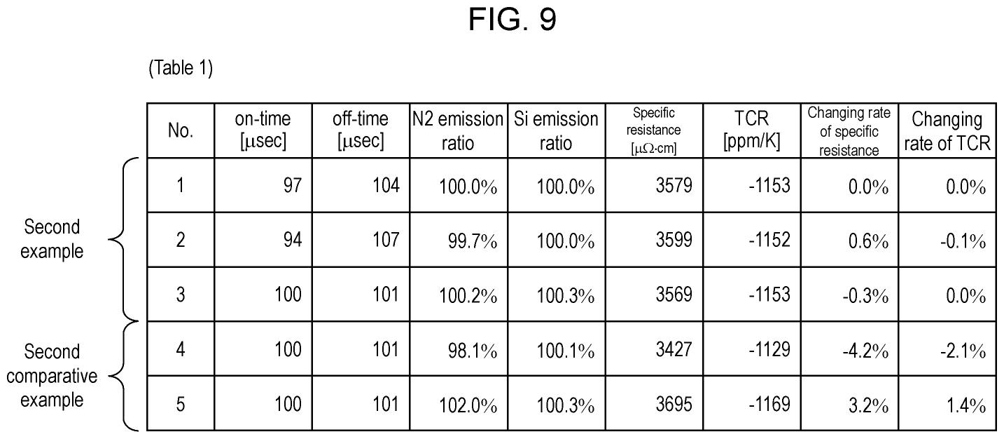

FIG. 9 shows results of the plasma emission intensity ratio, the specific resistance, and the TCR according to the second example and the second comparative example in which the film formation is performed under the above-described conditions. The specific resistance and the TCR were evaluated in a similar manner as in the first example.

In the second example, as a result of finely adjusting the pulse conditions such that the difference between the reference value and the N₂ emission intensity ratio is minimized, a variation in the N₂ emission intensity ratio is Δ0.5%, and a variation in the Si emission intensity ratio is Δ0.3%. As a result, it is found that a variation of the specific resistance is controlled to Δ0.9% and a variation of the TCR is controlled to Δ0.1%.

In the second comparative example, as a result of the film formation under the fixed film formation conditions, a variation in the N₂ emission intensity ratio was Δ3.9%, and a variation in the Si emission intensity ratio was Δ0.3%. As a result, it was found that a variation in the specific resistance was Δ7.4%, and a variation in the TCR was Δ3.5%.

Accordingly, in pulse sputtering device 10a, the variation in the emission intensity ratio is minimized. As a result, it is possible to prevent the variation in the specific resistance and the TCR, and it is possible to stably form a high-quality film for a long period of time.

### THIRD EXAMPLE

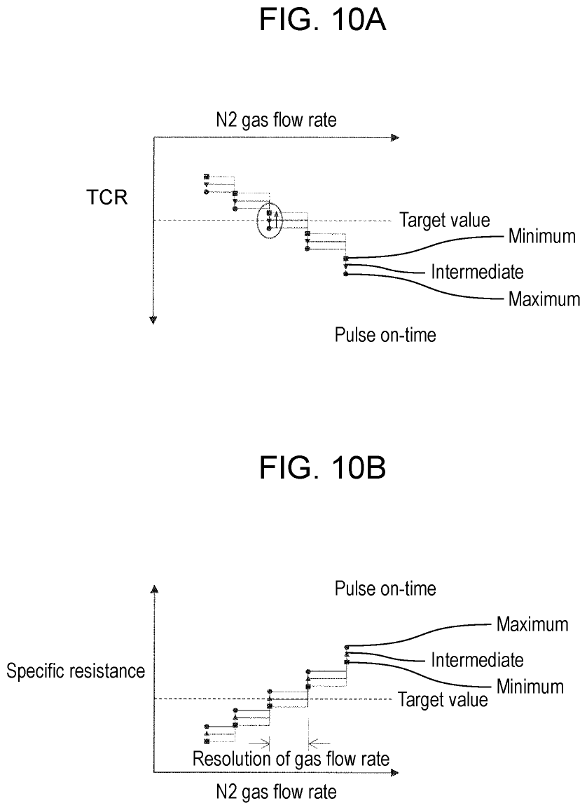

FIG. 10A is a graph showing a relationship between an N₂ gas flow rate and a TCR in a sputtering method according to a third example, and shows a case in which a pulse on-time is controlled from the minimum to the maximum. FIG. 10B is a graph showing a relationship between the N₂ gas flow rate and a specific resistance in the sputtering method according to the third example, and shows a case in which the pulse on-time is controlled from the minimum to the maximum.

FIGS. 10A and 10B are graphs summarizing a tendency of the TCR and the specific resistance with respect to the conditions of the pulse on-time and the conditions of the N₂ gas flow rate, assuming a composition of a certain target material. By providing such a graph, that is, a table of data, it is possible to form a film by precisely setting conditions such that the TCR and the specific resistance are target values. In FIGS. 10A and 10B, since a horizontal axis represents the N₂ gas flow rate, and the resolution of the gas flow rate is large and coarse, the graphs are stepwise. The three plots ●▴▪ are differences in the pulse on-time. Since the resolution of the pulse on-time can be precisely set to be small, the pulse on-time can be actually set to 50 or more stages instead of three stages. That is, when the pulse on-time is changed under the same gas flow rate condition, the specific resistance and the TCR can be finely changed.

### FIRST ADJUSTMENT EXAMPLE

For example, as the first adjustment example, a case in which the TCR is adjusted to a target value is considered. As shown in FIG. 10A, it can be found that the TCR tends to change to a negative side as the N₂ gas flow rate increases and to change to a positive side as the pulse on-time decreases.

Therefore, for example, the N₂ gas flow rate at which the TCR is lower than the target value may be set, the pulse on-time may be changed in a direction in which the pulse on-time is decreased from the maximum value, and the pulse on-time at which a difference from the target value is minimized may be set.

Instead of changing the pulse on-time alone, a duty ratio of the pulse ON may be changed. The duty ratio=ON time/(ON time+OFF time), and a tendency of changing the pulse on-time and a tendency of changing the duty ratio are the same. When the duty ratio is changed, since a frequency of the pulse is constant, a stability of the plasma discharge may be improved.

As shown in the graph of FIG. 10B, the specific resistance has a tendency opposite in positive and negative to the case of TCR, and it is sufficient to change an adjustment direction to an opposite direction. Therefore, the description will be omitted.

### FOURTH EXAMPLE

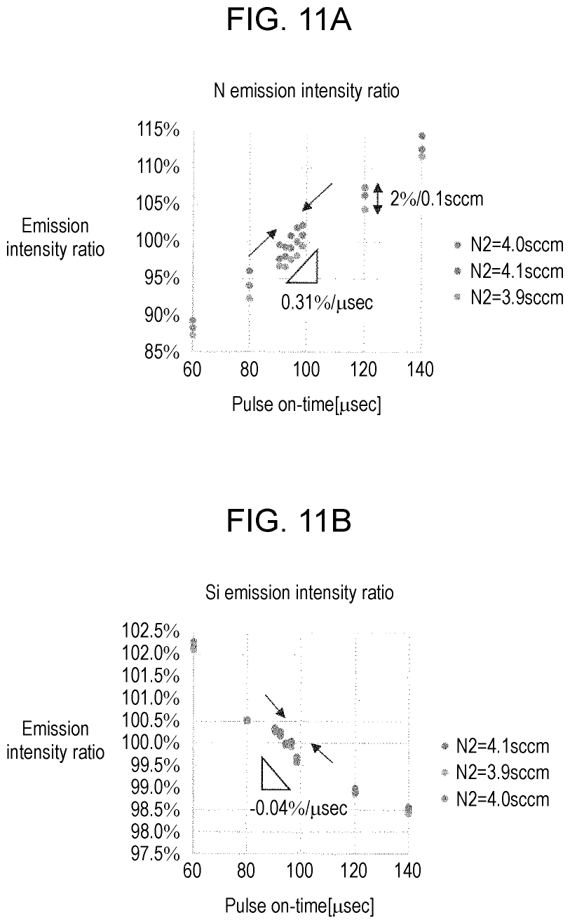

FIG. 11A is a graph showing a relationship between a pulse on-time and an N₂ emission intensity ratio in a sputtering method according to a fourth example, and shows a case in which an N₂ gas flow rate is changed. FIG. 11B is a graph showing a relationship between the pulse on-time and an Si emission intensity ratio in the sputtering method according to the fourth example, and shows a case in which the N₂ gas flow rate is changed.

FIGS. 11A and 11B are graphs summarizing results of an N emission ratio and a Si emission ratio with respect to conditions of the pulse on-time and conditions of the N₂ gas flow rate in a certain Cr—Si target composition. A changing rate of the N emission ratio with respect to the pulse on-time is 0.31%/μsec, and a changing rate of the N emission ratio with respect to the N₂ flow rate is approximately 2% per 0.1 sccm. On the other hand, a changing rate of the Si emission ratio with respect to the pulse on-time is −0.04%/μsec, and a change the Si emission ratio with respect to the N₂ flow rate may hardly be considered in a range of the graph. By providing such a graph, that is, a table of data, it can be found how the composition ratio can be controlled by changing the pulse condition with respect to the change of the emission ratio.

### SECOND ADJUSTMENT EXAMPLE

For example, as a second adjustment example, a case in which a composition ratio is adjusted to be constant, for example, a case in which a deviation of an N ratio is adjusted will be described.

A pulse on-time is changed such that the composition ratio obtained based on a plasma emission is constant. Specifically, as shown in FIG. 11A, when the N ratio is low, the pulse on-time is adjusted to be long as indicated by an arrow pointing to the upper right, and when the N ratio is high, the pulse on-time is adjusted to be short as indicated by an arrow pointing to the lower left. When the pulse on-time is changed, the Si ratio also changes. However, as shown in FIG. 11B, since a changing rate of an Si ratio is approximately one-tenth of a changing rate of the N ratio, an influence of the adjustment of approximately 5 μsec of the pulse on-time is small, and the change of the Si ratio is not problematic.

### THIRD ADJUSTMENT EXAMPLE

For example, as a third adjustment example, a case in which a composition ratio is adjusted to be constant, for example, a case in which a deviation of an Si ratio is adjusted will be described.

As shown in FIG. 11B, when the Si ratio is low, the pulse on-time is adjusted to be short as indicated by an arrow pointing to the upper left, and when the Si ratio is high, the pulse on-time is adjusted to be long as indicated by an arrow pointing to the lower right. When the pulse on-time is changed by 5 μsec or more, since a variation in an N ratio cannot be ignored, an N₂ flow rate is also changed by approximately 0.1 sccm in order to cancel the variation in the N ratio. That is, the N₂ flow rate is adjusted to be increased by approximately 0.1 sccm when the pulse on-time is shortened, and is adjusted to be decreased by approximately 0.1 sccm when the pulse on-time is lengthened.

As described above, when a composition is different depending on the lot of a target material or even when the target material is consumed due to film formation for a long time, a gas flow rate and a pulse condition can be changed according to a state of the target material from a spectrum of a plasma emission. Therefore, since a variation in electrical characteristics is minimized, for example, a nitride resistance thin film can be stably formed.

Appropriate combinations of any of the embodiments and/or examples among the various embodiments and/or examples described above are within the scope of the present disclosure, and effects of the embodiments and/or examples can be achieved.

The sputtering device and the sputtering method according to the present invention are useful for stable formation of nitride thin film devices such as a highly accurate resistance having a high resistance and a TCR of zero and a highly accurate thermistor having a large TCR and high sensitivity.

What is claimed is:

1. A sputtering device, comprising:
a vacuum chamber in which a target material and a substrate are disposable in a manner of facing each other;
a DC power supply being electrically connectable to the target material;
a gas supply source configured to introduce a film forming gas containing a nitrogen gas into the vacuum chamber; and
a pulsing unit configured to pulse a current flowing from the DC power supply to the target material, wherein
the sputtering device forms a nitride thin film having a ternary or more composition containing nitrogen on the substrate by generating plasma in the vacuum chamber using a sintered alloy target material having a binary or more composition as the target material.

2. The sputtering device of claim 1, further comprising:
a viewport configured to observe the plasma generated in the vacuum chamber;
a spectroscope configured to detect an emission spectrum of the plasma;
an emission spectrum calculator configured to calculate at least one of an emission intensity ratio of the target material and an emission intensity ratio of nitrogen based on a position and an intensity of a characteristic peak of the detected emission spectrum; and
a pulse controller configured to set an ON/OFF time of a pulse in the pulsing unit based on the calculated at least one emission intensity ratio.

3. A sputtering method using the sputtering device of claim 1, the sputtering method comprising:
setting an ON/OFF time of a pulse in the pulsing unit, and changing a composition ratio of a binary or more metal contained in the nitride thin film.

4. A sputtering method using the sputtering device of claim 2, the sputtering method comprising:
a step of measuring the plasma generated in the vacuum chamber by the spectroscope;
a step of normalizing an emission intensity of a current value of the measured emission peak of the plasma with a value of an emission intensity in a plasma state serving as a reference value recorded in advance to obtain a normalized emission intensity;
a step of calculating an emission intensity ratio of nitrogen in the entire film forming gas; and
a step of feedback-controlling a pulse on-time such that the emission intensity ratio of nitrogen minimizes a difference between the reference value and the current value.

5. A sputtering method, comprising:
a step of preparing a vacuum chamber in which a target material and a substrate are disposable in a manner of facing each other;
a step of electrically connecting a DC power supply to the target material;
a step of introducing a film forming gas containing a nitrogen gas into the vacuum chamber;
a step of detecting an emission spectrum of the plasma generated in the vacuum chamber;
a step of calculating an emission intensity ratio of a film forming gas containing the target material and a nitrogen gas based on a position and an intensity of a characteristic peak of the detected emission spectrum; and
a step of setting an ON/OFF time of a pulse based on the calculated emission intensity ratio of the film forming gas, and pulsing a current flowing through the target material.

6. A sputtering method of claim 5, further comprising:
a step of calculating, in the step of calculating the emission intensity ratio of the film forming gas, a normalized emission intensity of nitrogen obtained by normalizing a current value of an emission intensity at the characteristic peak of nitrogen in the detected emission spectrum with a value of an emission intensity of nitrogen in a plasma state serving as a reference value recorded in advance; and
a step of feedback-controlling a pulse on-time such that the emission intensity ratio of nitrogen in the entire film forming gas minimizes a difference between the reference value and the current value.
